(19) United States
(12) Patent Application Publication
(10) Pub. No.: US 2026/0011366 A1
(43) Pub. Date: Jan. 8, 2026

(54) INTEGRATED CIRCUIT MEMORY DEVICES HAVING RESISTIVE MEMORY CELLS THEREIN AND METHODS OF OPERATING SAME

(71) Applicant: Samsung Electronics Co., Ltd., Suwon-si (KR)

(72) Inventors: Minsup Kim, Suwon-si (KR); Yonghwan Kim, Suwon-si (KR); Seongsu Eom, Suwon-si (KR)

(21) Appl. No.: 19/020,160

(22) Filed: Jan. 14, 2025

(30) Foreign Application Priority Data
Jul. 8, 2024 (KR) 10-2024-0089376

(51) Int. Cl. G11C 13/00; G11C 5/06

(52) U.S. Cl. CPC G11C 13/0069; G11C 5/063; G11C 13/0026; G11C 13/0028; G11C 13/004

(57) ABSTRACT

A memory device includes an array of resistive memory cells, row and column decoders, a control circuit and a write/read circuit coupled to the column decoder and the control circuit. The write/read circuit is configured to perform a write operation that transfers write data into a target page of resistive memory cells. A first resistive memory cell includes: a variable resistor element having a first terminal coupled to a first source line, and first and second selection transistors configured in combination as a CMOS transmission gate having a first current carrying terminal coupled to a first bit line, a second current carrying terminal coupled to a second terminal of the variable resistor element, and a gate terminal coupled to a first word line. A first write driver within the write/read circuit is configured to selectively perform a set write operation and a reset write operation on the variable resistor element.

### REFERENCE TO PRIORITY APPLICATION

This US application claims priority under 35 U.S.C. § 119 to Korean Patent Application No. 10-2024-0089376, filed Jul. 8, 2024, the disclosure of which is hereby incorporated herein by reference.

### BACKGROUND

Example embodiments described herein relate to memory devices, and more particularly, to resistive memory devices and/or methods of operating resistive memory devices.

Volatile memory is a type of computer storage that only maintains its data while the device is powered. Non-volatile memory is a type of computer storage that can maintain stored information even after having been power cycled (e.g. after loss of power). Research into next-generation memory devices that are non-volatile and do not require refresh operations is being conducted in response to demands for higher capacity and lower power consumption memory devices. Next-generation memory devices generally require/include the high integrity characteristics of Dynamic Random Access Memory (DRAM), the non-volatile characteristics of flash memory, and the high speed of static RAM (SRAM). Examples of next-generation memory devices include Phase change RAM (PRAM), Nano Floating Gate Memory (NFGM), Polymer RAM (PoRAM), Magnetic RAM (MRAM), Ferroelectric RAM (FeRAM), and/or Resistive RAM (RRAM), for example.

### SUMMARY

Some example embodiments provide resistive memory devices having enhanced performance.

Some example embodiments provide methods of operating resistive memory devices, which enhance operating performance.

According to some example embodiments, a resistive memory device includes a memory cell array including a plurality of resistive memory cells, a write/read circuit and a control circuit. The write/read circuit is connected to the memory cell array through a row decoder and through a column decoder, and is configured to perform a write operation to write a write data in a target page of the memory cell array. The control circuit controls the row decoder, the column decoder and the write/read circuit based on a command and an address, etc. A first resistive memory cell of the target page among the plurality of resistive memory cells includes a variable resistor element coupled to a first source line and two selection transistors having different conductivity types. The two selection transistors are coupled in parallel (as a CMOS transmission gate) to a first bit-line and have gate terminals coupled together and to a first word line. The first source line is coupled to the column decoder and a first write driver in the write/read circuit. The first write driver performs a set write operation using one of the two selection transistors and performs a reset write operation using the other of the two selection transistors.

According to some example embodiments, there is provided a method of operating a resistive memory device including a memory cell array that includes a plurality of resistive memory cells. According to the method, a write command is received from an external memory controller, an address and a data are received from the external memory controller, a reset write operation is performed on a target page by applying a ground voltage to a first word-line, and a set write operation is performed on a portion of the target page by applying a power supply voltage to the first word-line based on the data. Each of resistive memory cells the target page includes a variable resistor element coupled to each of source lines and two selection transistors having different conductivity types; the two selection transistors are coupled in parallel to a corresponding bit line, and have gate terminals coupled in common to each other and to a corresponding word line. Each of the source lines is coupled to the column decoder and write drivers (via the column decoder).

According to some example embodiments, a resistive memory device includes a memory cell array including a plurality of resistive memory cells, a write/read circuit and a control circuit. The write/read circuit is connected to the memory cell array through a row decoder and through a column decoder, and performs a write operation to write a write data in a target page of the memory cell array. The control circuit controls the row decoder, the column decoder and the write/read circuit based on a command and an address. A first resistive memory cell of the target page among the plurality of resistive memory cells includes a variable resistor element coupled to a first source line and two selection transistors having different conductivity types. The first and second selection transistors are coupled in parallel to a first bit line and have gate control terminals electrically coupled together and to a first word line; the first source line is coupled to the column decoder and a first write driver in the write/read circuit. According to some embodiments, the first selection transistor has a first conductivity type and the second selection transistor has a second conductivity type different from the first conductivity type. The first write driver performs a set write operation using the first selection transistor that operates in a saturation region and performs a reset write operation using the second selection transistor that operates in a saturation region.

Accordingly, the resistive memory device includes a plurality of resistive memory cells, and each of the plurality of resistive memory cells includes a variable resistor element coupled to a source line and two selection transistors coupled in parallel to a word-line, a bit-line and the variable resistor element. The resistive memory device performs a set write operation using one of the two selection transistors, which operates in a saturation region and may perform a reset write operation using the other of the two selection transistors, which operates in a saturation region. Therefore, because the selection transistor operates in the saturation region when the write operation is performed, a write current having enough magnitude is generated when the power supply voltage is applied to the bit-line. Accordingly, the nonvolatile memory device may reduce power consumption and enhance performance by increasing uniformity characteristics of the resistive memory cells.

Moreover, according to further embodiments, a nonvolatile resistive memory device is provided with an array of resistive memory cells having respectively pluralities of word, bit and source lines electrically connected thereto. Row and column decoders are provided, along with a control circuit, which is electrically coupled to the row and column decoders. A write/read circuit is provided, which is electrically coupled to the column decoder and the control circuit. The write/read circuit is configured to perform a write operation that transfers write data into a target page of resistive memory cells within the array. In addition, a first resistive memory cell within the array includes: (i) a variable resistor element having a first terminal electrically coupled to a first source line within the plurality thereof, and (ii) first and second selection transistors configured in combination as a CMOS transmission gate having a first current carrying terminal electrically coupled to a first bit line within the plurality thereof, a second current carrying terminal electrically coupled to a second terminal of the variable resistor element, and a gate control terminal electrically coupled to a first word line within the plurality thereof. Advantageously, a first write driver within the write/read circuit is configured to perform a set write operation on the variable resistor element using the first selection transistor within the CMOS transmission gate to establish a first current path in a first direction through the variable resistor element, and perform a reset write operation on the variable resistor element using the second selection transistor within the CMOS transmission gate to establish a second current path in a second direction through the variable resistor element, which is opposite the first direction.

In still further embodiments, a nonvolatile resistive memory device is provided, which includes an array of resistive memory cells having pluralities of word, bit and source lines electrically connected thereto, with each of the resistive memory cells respectively including a variable resistor element and a CMOS transmission gate electrically connected in series with the variable resistor element. Row and column decoders are provided, along with a control circuit that is electrically coupled to the row and column decoders. A write/read circuit is provided, which is electrically coupled to the column decoder and the control circuit. The write/read circuit is configured to perform: (i) a set write operation that transfers write data into a target page of resistive memory cells within the array using first selection transistors within a corresponding plurality of CMOS transmission gates to establish first current paths in a first direction through the variable resistor elements in the target page, and (ii) a reset write operation on the target page of resistive memory cells using second selection transistors within the corresponding CMOS transmission gate to establish second current paths in a second direction through the variable resistor elements, which are opposite the first direction.

### BRIEF DESCRIPTION OF THE DRAWINGS

The above and other features of the present disclosure will be more clearly understood by describing in detail example embodiments thereof with reference to the accompanying drawings.

FIG. 1 is a block diagram illustrating a memory system according to some example embodiments.

FIG. 2 is a block diagram illustrating an example of the memory controller in FIG. 1 according to some example embodiments.

FIG. 3 is a block diagram illustrating an example of the resistive memory device in FIG. 1 according to some example embodiments.

FIG. 4 is a circuit diagram illustrating an example of the memory cell array in FIG. 3 according to some example embodiments.

FIG. 5A is a circuit diagram illustrating one of the resistive memory cells in FIG. 4 according to example embodiments.

FIG. 5B is a circuit diagram illustrating one of the resistive memory cells in FIG. 4 according to example embodiments.

FIG. 6 is a diagram illustrating an example of the memory cell array in FIG. 3 according to example embodiments.

FIG. 7A is a graph showing set write operation and reset write operation for the variable resistor element of the resistive memory cell of FIGS. 5A and 5B.

FIG. 7B is a graph showing a distribution of resistive memory cells according to resistance when the resistive memory cell of FIGS. 5A and 5B is a single level cell.

FIG. 8 is a graph showing a relationship between a drain-source voltage and a drain-source current of a first selection transistor in the resistive memory cell of FIG. 5A according to example embodiments.

FIG. 9 is a block diagram illustrating an example of the control circuit in the resistive memory device of FIG. 3 according to some example embodiments.

FIG. 10 illustrates a portion of the resistive memory device of FIG. 3 according to example embodiments.

FIG. 11 illustrates an example of a first resistive memory cell and a first write driver in the resistive memory device of FIG. 10 according to example embodiments.

FIG. 12A illustrates an example of a first resistive memory cell and a first write driver in the resistive memory device of FIG. 10 during a set write operation according to example embodiments.

FIG. 12B illustrates an example of a first resistive memory cell and a first write driver in the resistive memory device of FIG. 10 during a reset write operation according to example embodiments.

FIG. 13 illustrates an example of a first resistive memory cell and a first write driver in the resistive memory device of FIG. 10 according to example embodiments.

FIG. 14A illustrates an example of a first resistive memory cell and a first write driver in the resistive memory device of FIG. 10 during a set write operation according to example embodiments.

FIG. 14B illustrates an example of a first resistive memory cell and a first write driver in the resistive memory device of FIG. 10 during a reset write operation according to example embodiments.

FIG. 15 is a circuit diagram illustrating an example of a first write driver in the resistive memory device of FIG. 10 according to example embodiments.

FIG. 16A illustrates an example operation of the first write driver of FIG. 15 in a stand-by state according to example embodiments.

FIG. 17 illustrates a circuit diagram illustrating components associated with performing a read operation of a resistive memory device according to example embodiments.

FIG. 18 is a flow chart illustrating a method of operating a resistive memory device according to example embodiments.

FIG. 19 is a flow chart illustrating a method of operating a resistive memory device according to example embodiments.

FIG. 20 is a flow chart illustrating a method of operating a resistive memory device according to example embodiments.

FIG. 21 illustrates a memory device having a cell over peripheral (COP) structure according to example embodiments.

FIG. 22 is a block diagram illustrating a mobile system according to some example embodiments.

### DETAILED DESCRIPTION

Example embodiments of the present disclosure will be described more fully hereinafter with reference to the accompanying drawings. Like reference numerals may refer to like elements throughout this application.

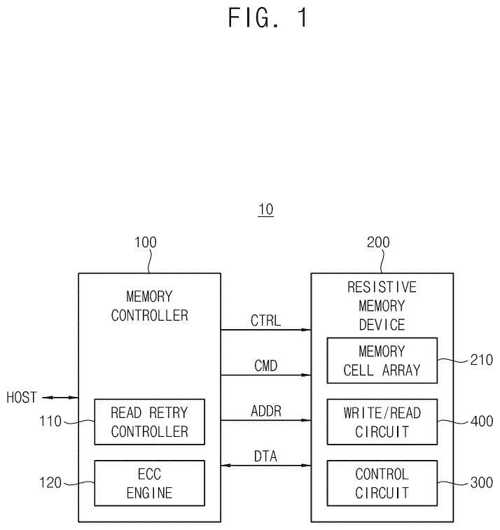

FIG. 1 is a block diagram illustrating a memory system according to some example embodiments. In these example embodiments, a memory device may be referred to as a resistive type memory device because the memory device includes resistive type memory cells. Alternatively or additionally, the memory device may include various types of memory cells. For example, the memory device may include a heterogeneous collection of memory cells. Since the memory cells may be disposed at cross-points of multiple first signal lines, multiple second signal lines and multiple third signal lines, the memory device may be referred to as a cross-point memory device.

Referring to FIG. 1, a memory system 10 may include a memory controller 100 and a resistive memory device 200. The resistive memory device 200 may include a memory cell array 210, a control circuit 300, and a write/read circuit 400. The memory cell array 210 may include a plurality of resistive (type) memory cells. In response to a write/read request from a host, the memory controller 100 may read data stored in the resistive memory device 200 and/or may control the resistive memory device 200 to write data to the resistive memory device 200. In some example embodiments, the memory controller 100 may provide an address (signal) ADDR, a command (signal) CMD, and a control signal CTRL to the resistive memory device 200 to control a program (or write) operation and/or a read operation with respect to the resistive memory device 200.

In addition, write-target data DTA and read data DTA may be exchanged between the memory controller 100 and the resistive memory device 200. For example, the write-target data DTA may be written to the resistive memory device 200 in response to a write command and the read data DTA may be read from the resistive memory device 200 in response to a read command. In addition, the memory controller 100 may include a read-retry controller 110 (e.g., a control circuit) and/or an error correction code (ECC) engine 120 (e.g., an ECC circuit). The ECC engine 120 may perform error detection and correction on data that is provided from the resistive memory device 200. For example, the ECC engine 120 may detect whether the data has an error and potentially correct the error.

Although not illustrated, the memory controller 100 may include a random access memory (RAM), a processing unit, a host interface, and/or a memory interface. The RAM may be used as an operation memory of the processing unit. The processing unit may control operations of the memory controller 100. The host interface may include a protocol for exchanging data between the host and the memory controller 100. The memory interface may include a protocol for exchanging data between the memory controller 100 and the resistive memory device 200.

The memory cell array 210 may include a plurality of resistive memory cells that are disposed respectively in regions where first signal lines, second signal lines and third signal lines cross. In addition, each of the resistive memory cells may be a single level cell (SLC) that stores one bit data, or may be a multilevel cell (MLC) that stores two or more bits of data per cell. Alternatively, the memory cell array 210 may include both the SLCs and the MLCs.

As will be understood by those skilled in the art, when one bit data is written to one memory cell, the memory cells may have two resistance level distributions according to the written data. Alternatively, when two-bit data is written to one memory cell, the memory cells may have four resistance level distributions according to the written data. In another embodiment, when a memory cell is a triple level cell (TLC) that stores three-bit data, the memory cells may have eight resistance level distributions according to the written data. However, embodiments of the inventive concept are not limited thereto. For example, each of the memory cells may store at least four-bit data in another embodiment. In some example embodiments, the memory cell array 210 may include memory cells with a two-dimensional horizontal structure. Alternatively or additionally, the memory cell array 210 may include memory cells with a three-dimensional vertical structure.

The memory cell array 210 may include resistive-type (resistive) memory cells that include a variable resistor element. For one example, when resistance of the variable resistor element that is formed of a phase change material (e.g., Ge—Sb—Te) is changed according to a temperature, a resistive memory device is a phase change RAM (PRAM). As another example, when the variable resistor element is formed of a complex metal oxide including an upper electrode, a lower electrode, and a transition metal oxide therebetween, the resistive memory device is a resistive RAM (RRAM). As another example, when the variable resistor element is formed of an upper electrode of a magnetic material, a lower electrode of the magnetic material, and a dielectric therebetween, the resistive memory device is a magnetic RAM (MRAM).

The write/read circuit 400 may perform a write operation and a read operation on the memory cells. In some example embodiments, the write/read circuit 400 may be connected to the memory cells through a plurality of bit-lines and a plurality of source lines, and may include write drivers (e.g., driving circuits) that write data to the memory cells, and sense amplifiers that sense resistive components of the memory cells.

In some example embodiments, the control circuit 300 may control operations of the resistive memory device 200, and may control the write/read circuit 400 so as to perform a memory operation such as a write operation or a read operation. For the write and read operations of the resistive memory device 200, the control circuit 300 may provide pulse signals such as a write pulse or a read pulse to the write/read circuit 400. For example, the write/read circuit 400 may provide a write current (or a write voltage) in response to the write pulse to the memory cell array 210 and provide a read current (or a read voltage) in response to the read pulse to the memory cell array 210. The read current/write current or the read voltage/write voltage may be the same as, or different from, each other.

In the write operation on the resistive memory device 200, a resistance value of a variable resistor of a memory cell of the memory cell array 210 may be increased or decreased, depending on write data associated with the write operation. For example, each of the memory cells of the memory cell array 210 may have a resistance value according to data that is currently stored therein, and the resistance value may be increased or decreased, depending on data to be written to each of the memory cells.

In some example embodiments, the write operation is divided into a reset write operation and a set write operation. In a set state, a resistive memory cell may have a relatively low resistance value, and in a reset state, the resistive memory cell may have a relatively high resistance value. The reset write operation may involve performing a write operation so as to increase a resistance value of a variable resistor of the resistive memory cell, and the set write operation may involve performing a write operation so as to decrease the resistance value of the variable resistor of the resistive memory cell.

In some example embodiments, when a detected error of data read by the resistive memory device 200 is not correctable, the memory controller 100 may control the resistive memory device 200 to operate in a read-retry mode to perform a read-retry operation. For example, the ECC engine 120 may determine whether the data read has an error and whether that error is correctable. During the read-retry operation, the memory device 200 may read (or re-read) data while the memory device 200 changes a reference (e.g., a read reference) for determining data “0” and data “1”, analyzes a valley in a resistance level distribution of memory cells by performing a data determination operation on the read data, and based on the analysis result, perform a recovery algorithm of selecting a read reference so as to minimize or reduce error occurrence of the data.

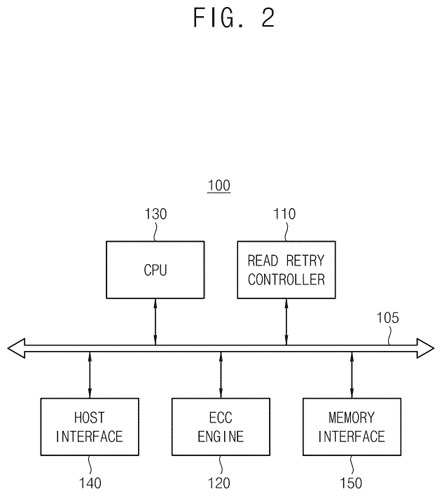

FIG. 2 is a block diagram illustrating an example of the memory controller in FIG. 1 according to some example embodiments. Referring to FIG. 2, the memory controller 100 may include the read-retry controller 110, the ECC engine 120, a central processing unit (CPU) 130, a host interface 140, and a memory interface 150. The read-retry controller 110, the ECC engine 120, the CPU 130, the host interface 140, and the memory interface 150 may communicate with one another through a system bus 105.

The CPU 130 may control operations of the memory controller 100. For example, the CPU 130 may control various function blocks related to a memory operation on the resistive memory device 200. The host interface 140 may interface with the host. Examples of this interfacing may include receiving a request for the memory operation from the host. For example, the host interface 140 may receive, from the host, requests for reading and/or writing data, and in response to the requests, the host interface 140 may generate internal signals for the memory operation on the resistive memory device 200.

In some example embodiments, the ECC engine 120 may perform an ECC encoding process on write data and an ECC decoding process on read data. For example, the ECC engine 120 may perform an error detection operation on data that is read from the resistive memory device 200, and may perform an error correction operation on the read data when a result of the error detection operation indicates an error is present. The read-retry controller 110 may provide various types of information for controlling an operation of the resistive memory device 200 during the read-retry mode, as previously described. The memory interface 150 may interface with the resistive memory device 200 to exchange various signals (e.g., command, address, mode signals, reference information, data, etc.) between the memory controller 100 and the resistive memory device 200.

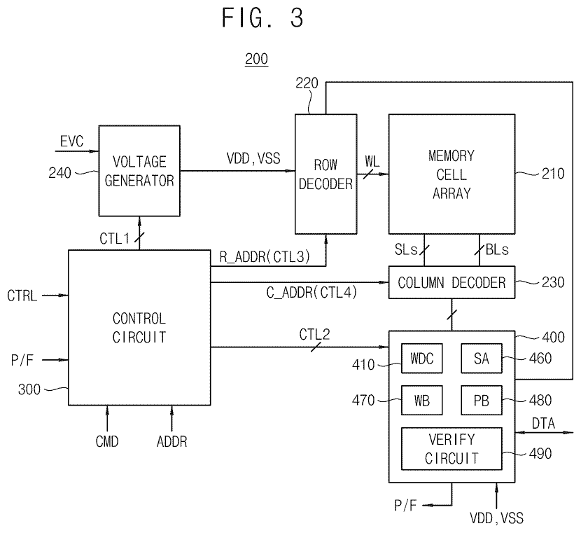

FIG. 3 is a block diagram illustrating an example of the resistive memory device in FIG. 1 according to some example embodiments. Referring to FIG. 3, the resistive memory device 200 may include the memory cell array 210, the control circuit 300 and the write/read circuit 400. The resistive memory device 200 may further include a row decoder 220, a column decoder 230 and a voltage generator 240. The write/read circuit 400 may include a write driver circuit WDC 410, a read circuit SA 460, a write buffer WB 470, a page buffer PB 480 and a verify circuit 490. The read circuit 460 may be referred to as a sense amplifier.

Resistive memory cells that are arranged in the memory cell array 210 are connected to word-lines WLs, bit-lines BLs and source lines SLs. Since various voltage signals or current signals are provided via the bit-lines BLs, the source lines SLs and the word-lines WLs, data may be written to or read from selected memory cells, and writing data to or reading data from residual unselected memory cells may be prevented. The address (or, access address) ADDR accompanied with the command CMD for indicating an access-target memory cell may be received by the control circuit 300. In an embodiment, the address ADDR may include a row address R_ADDR for selecting word-lines WLs of the memory cell array 210, and a column address C_ADDR for selecting bit-lines BLs of the memory cell array 210. The row decoder 220 may perform a word-line selecting operation in response to the row address R_ADDR, and the column decoder 230 may perform a bit-line selecting operation in response to the column address C_ADDR. The write/read circuit 400 may be connected to the bit-lines BLs and thus may write data to a memory cell or may read data from the resistive memory cells. The write/read circuit 400 may be connected to the row decoder 220 and the column decoder 230. Through the specification, ‘connected’ or ‘coupled’ may mean ‘electrically connected’ or ‘electrically coupled’.

In addition, a power supply voltage (e.g., a first driving voltage) VDD and a ground voltage (e.g., a second driving voltage) may be provided from the voltage generator 240 to a selected memory cell, and inhibit voltages may be provided from the voltage generator 240 to unselected word-lines and unselected bit-lines, and during a read operation, a read voltage may be provided from the voltage generator 240 to the selected memory cell.

The write/read circuit 400 may provide a write voltage or a write current according to data to the memory cell array 210 via the column decoder 230. In addition, in order to determine the data in the read operation, the write/read circuit 400 may include a comparator that is connected to a node (e.g., a data sensing node) of a bit-line BL, and may read a data value by performing a comparison operation on a sensing voltage or a sensing current of the sensing node. In addition, the write/read circuit 400 may provide the control circuit 300 with a pass/fail signal P/F according to a read result with respect to the read data. The control circuit 300 may refer to the pass/fail signal P/F and thus control write and read operations of the memory cell array 210. The write/read circuit 400 may perform a write operation to transfer write data into a target page in the memory cell array 210.

In example embodiments, the control circuit 300 may generates a plurality of control signals CTL1, CTL2, CTL3 and CTL4 based on the command CMD, the address ADDR, the control signal CTRL and the pass/fail signal P/F. In an embodiment, the control circuit 300 may provide a first control signal CTL1 to the voltage generator 240, provide a second control signal CTL2 to the write/read circuit 400, provide a third control signal CTL3 to the row decoder 220 and provide a fourth control signal CTL4 to the column decoder 230. The voltage generator 240 may generate the power supply voltage VDD and the ground voltage VSS based on the external voltage EVC and may provide the power supply voltage VDD and the ground voltage VSS to the row decoder 220 and the write/read circuit 400.

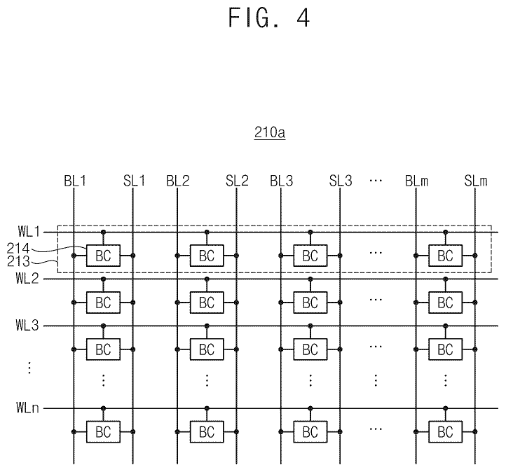

FIG. 4 is a circuit diagram illustrating an example of the memory cell array in FIG. 3 according to some example embodiments. A memory cell array 210a includes multiple cells, and FIG. 4 shows an example of a cell array having a cell block including these multiple cells. Referring to FIG. 4, a memory cell array 210a includes a plurality of word-lines WL1, WL2, WL3, . . . , WLn, a plurality of bit-lines BL1, BL2, BL3, . . . , BLm, a plurality of source lines SL1, SL2, SL3, . . . , SLm and a plurality of resistive memory cells BC 214. Here, n may be a natural number greater than 3 and m may a natural number greater than 3. The plurality of resistive memory cells 214 coupled to a same word-line may be defined as a page 213.

Each of the plurality of resistive memory cells 214 may be referred to as a bit-cell. Each of the plurality of resistive memory cells 214 may include a variable resistor element coupled to respective one of the plurality of source lines SL1, SL2, SL3, . . . , SLm and first and second selection transistors coupled to respective one of the plurality of word-lines WL1, WL2, WL3, . . . , WLn. The variable resistor element may be also referred to as a variable resistor. One of the first and second selection transistors may be turned on during a set write operation and may provide a current path and the other of the first and second selection transistors may be turned on during a reset write operation and may provide a current path.

A resistance value of the variable resistor element may be changed to one of multiple resistive states. For example, the resistance value may change in response to an electric pulse being applied to the corresponding variable resistor element. In an embodiment, the variable resistor element may include a phase-change material having a crystal state that changes according to a current. The phase-change material may include materials, such as GaSb, InSb, InSe, or Sb₂Te₃ obtained by compounding two elements, GeSbTe, GaSeTe, InSbTe, SnSb₂Te₄, or InSbGe obtained by compounding three elements, or AgInSbTe, (GeSn)SbTe, GeSb(SeTe) obtained by compounding four elements.

In some example embodiments, the phase-change material has an amorphous state that is relatively high-resistive, and a crystal state that is relatively low-resistive. A phase of the phase-change material may be changed by Joule heat that is generated by the current. Using changes of the phase, data may be written to the corresponding cell. In another embodiment, the variable resistor element does not include the phase-change material, but includes perovskite compounds, transition metal oxide, magnetic materials, ferromagnetic materials, or antiferromagnetic materials, for example.

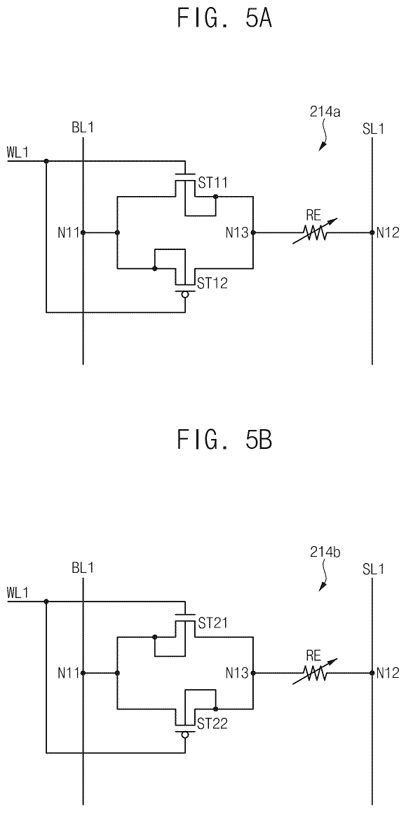

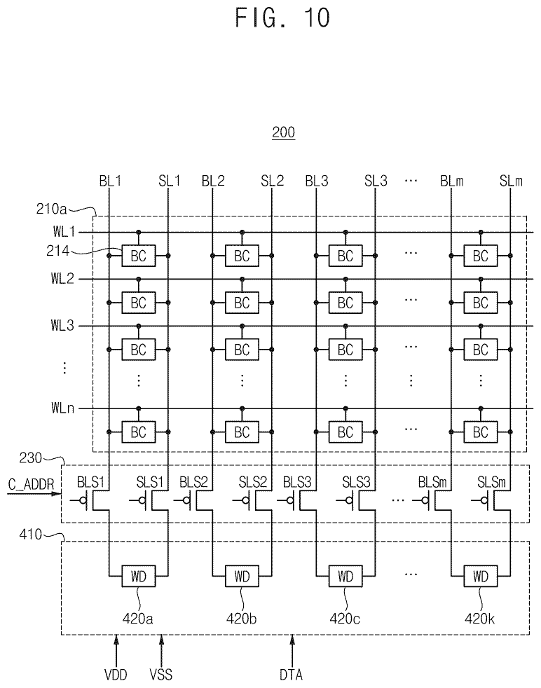

FIG. 5A is a circuit diagram illustrating one of the resistive memory cells in FIG. 4 according to example embodiments. Referring to FIG. 5A, a resistive memory cell 241a may include a variable resistor element RE and two selection transistors ST11 and ST12. The variable resistor element RE may be coupled to a first source line SL1 that is coupled to the column decoder 230 in FIG. 3 and a first write driver (420a in FIG. 10) in the write/read circuit 400. The two selection transistors ST11 and ST12 may be coupled to the variable resistor element RE, a first word-line WL1 at a first node N11 and a first bit-line BL1 with respect to each other. The variable resistor element RE may be coupled between a second node N12 coupled to the first source line SL1 and a third node N13.

A first selection transistor ST11 may include an n-type metal-oxide semiconductor (NMOS) transistor having a first conductivity type and a second selection transistor ST12 may include a p-type metal-oxide semiconductor (PMOS) transistor having a second conductivity type different from the first conductivity type. The first selection transistor ST11 may be coupled between the first node N11 coupled to the first bit-line BL1 and the third node N13 coupled to the variable resistor element RE, may have a gate coupled to the first word-line WL1 and may have a body coupled to the third node N13. The second selection transistor ST12 may be coupled between the first node N11 and the third node N13, may have a gate coupled to the first word-line WL1 and may have a body coupled to the first node N11. The two selection transistors ST11 and ST12 may be configured in combination as CMOS transmission gate having a first current carrying terminal coupled to the first bit-line BL1 and a second current carrying terminal coupled to the first word-line WL1.

The first write driver 420a in FIG. 10 may perform a set write operation by using the first selection transistor ST11 and may perform a reset write operation by using the second selection transistor ST12. The first write driver 420a may perform a set write operation by using the first selection transistor ST11 that is enabled and may perform a reset write operation by using the second selection transistor ST12 that is enabled. That is, the first write driver 420a in FIG. 10 may perform a set write operation on the variable resistor element RE using the selection transistor ST11 within the CMOS transmission gate to establish a first current path in a first direction through the variable resistor element RE, and perform a reset write operation on the variable resistor element RE using the selection transistor ST12 within the CMOS transmission gate to establish a second current path in a second direction through the variable resistor element, which is opposite the first direction.

FIG. 5B is a circuit diagram illustrating one of the resistive memory cells in FIG. 4 according to example embodiments. Referring to FIG. 5B, a resistive memory cell 241b may include a variable resistor element RE and two selection transistors ST21 and ST22. The variable resistor element RE may be coupled to a first source line SL1 that is coupled to the column decoder 230 in FIG. 3 and a first write driver (420a in FIG. 10) in the write/read circuit 400. The two selection transistors ST21 and ST22 may be coupled to the variable resistor element RE, a first word-line WL1 at a first node N11 and a first bit-line BL1 in parallel with respect to each other. The variable resistor element RE may be coupled between a second node N12 coupled to the first source line SL1 and a third node N13.

A first selection transistor ST21 may include an NMOS transistor having a first conductivity type and a second selection transistor ST22 may include a PMOS transistor having a second conductivity type different from the first conductivity type. The first selection transistor ST21 may be coupled between the first node N11 coupled to the first bit-line BL1 and the third node N13 coupled to the variable resistor element RE, may have a gate coupled to the first word-line WL1 and may have a body coupled to the first node N11. The second selection transistor ST12 may be coupled between the first node N11 and the third node N13, may have a gate coupled to the first word-line WL1 and may have a body coupled to the third node N13.

The first write driver 420a in FIG. 10 may perform a set write operation by using the second selection transistor ST22 and may perform a reset write operation by using the first selection transistor ST21. The first write driver 420a may perform a set write operation by using the second selection transistor ST22 that is enabled and may perform a reset write operation by using the first selection transistor ST21 that is enabled.

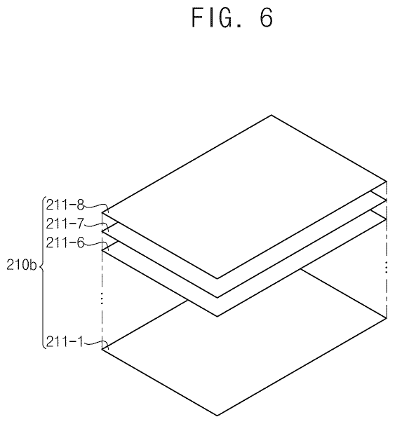

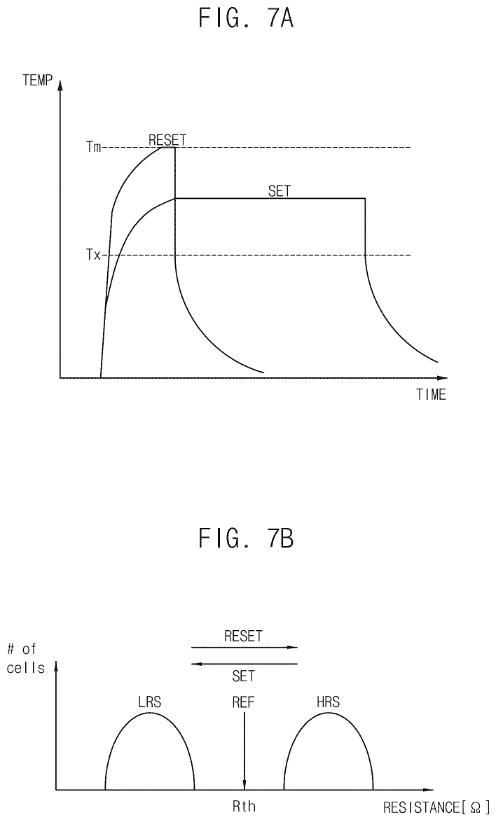

FIG. 6 is a diagram illustrating an example of the memory cell array in FIG. 3 according to example embodiments. Referring to FIG. 6, a memory cell array 210b is implemented with a three-dimensional stacked structure. The example three-dimensional stacked structure includes multiple, vertically stacked, memory cell layers 211_1, . . . , 211_6, 211_7 and 211_8. However, those of ordinary skill in the art will understand that the number of vertically stacked memory cell layers is an arbitrary one.

When the memory cell array 210b has a three-dimensional laminated structure, each of the memory cell layers 211_1, . . . , 211_6, 211_7 and 211_8 has the cross point structure illustrated in FIG. 4.

FIG. 7A is a graph showing set write operation and reset write operation for the variable resistor element of the resistive memory cell of FIGS. 5A and 5B and FIG. 7B is a graph showing a distribution of resistive memory cells according to resistance when the resistive memory cell of FIGS. 5A and 5B is a single level cell. Referring to FIGS. 5A, 5B and 7A together, a horizontal axis of FIG. 7A represents time and a vertical axis of FIG. 7A represents temperature TEMP. When a phase change material constituting the variable resistor element RE is heated to a temperature between a crystallization temperature Tx and a melting point Tm for a certain period of time and then gradually cooled, the phase change material is in a crystalline state. This crystalline state is referred to as a ‘set state’ in which data ‘1’ is stored. On the other hand, when the phase change material is quenched after being heated to a temperature above the melting point Tm, the phase change material is in an amorphous state. This amorphous state is referred to as a ‘reset state’ in which data ‘0’ is stored. Therefore, a current may be supplied to the variable resistor element RE to store data, and the resistance value of the variable resistor element RE may be measured to read data.

Referring to FIGS. 5A, 5B and 7B together, a horizontal axis of FIG. 7B represents resistance and a vertical axis of FIG. 7B represents the number of resistive memory cells. When the resistive memory cell (for example, the resistive memory cell 124) is a single level cell, the resistive memory cell may be in one of a low resistance state LRS, that is, a set state SET, and a high resistance state HRS, that is, a reset state RESET. Accordingly, the operation of switching the resistive memory cell 124 from the low resistance state LRS to the high resistance state HRS may be referred to as a reset operation or a reset write operation. In addition, the operation of switching the resistive memory cell 124 from the high resistance state HRS to the low resistance state LRS may be referred to as a set operation or a set write operation.

A resistance between the distribution of the low resistance state LRS and the distribution of the high resistance state HRS may be set to be a threshold resistance Rth. In a read operation performed on the resistive memory cells, when a read result is equal to or greater than the threshold resistance Rth, the read result may be determined to be high resistance state HRS, and when the read result is less than the threshold resistance Rth, the read result may be determined to be the low resistance state LRS. In an embodiment, information on read reference REF corresponding to the threshold resistance Rth may be received from the memory controller 100.

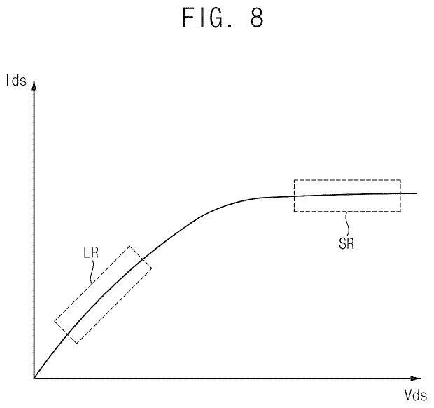

FIG. 8 is a graph showing a relationship between a drain-source voltage and a drain-source current of a first selection transistor in the resistive memory cell of FIG. 5A according to example embodiments. Referring to FIG. 8, as a drain-source voltage Vds of the first selection transistor ST11 increases, a drain-source current Ids of the first selection transistor ST11 linearly increases and is maintained at a constant value. When the first selection transistor ST11 operates in a linear region LR, the drain-source current Ids of the first selection transistor ST11 linearly increases in response to the drain-source voltage Vds of the first selection transistor ST11 and when first selection transistor ST11 operates in a saturation region SR, the drain-source current Ids of the first selection transistor ST11 is maintained at a substantially constant value even though the drain-source voltage Vds of the first selection transistor ST11 increases.

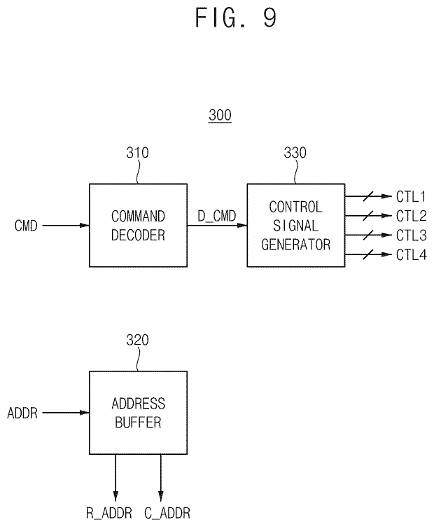

FIG. 9 is a block diagram illustrating an example of the control circuit in the resistive memory device of FIG. 3 according to some example embodiments. Referring to FIG. 9, the control circuit 300 may include a command decoder 310, an address buffer 320 and a control signal generator 330. The command decoder 310 may generate a decoded command D_CMD by decoding the command CMD, and may provide the decoded command D_CMD to the control signal generator 330. The address buffer 320 may receive the address ADDR, may provide the row address R_ADDR to the row decoder 220 and may provide the column address C_ADDR to the column decoder 230.

The control signal generator 330 may receive the decoded command D_CMD and may generate the first through fourth control signals CTL1˜CTL4 based on an operation designated by the decoded command D_CMD. The control signal generator 340 may provide the first control signal CTL1 to the voltage generator 240, may provide the second control signal CTL2 to the write/read circuit 400, may provide the third control signal CTL3 to the row decoder 220 and may provide the fourth control signal CTL4 to the column decoder 230.

FIG. 10 illustrates a portion of the resistive memory device of FIG. 3 according to example embodiments. Referring to FIG. 10, the resistive memory device 200 includes the memory cell array 210a, the row decoder 220, the column decoder 230 and a write driver circuit 410. The column decoder 230 may include a plurality of bit-line switches BLS1, BLS2, BLS3, . . . , BLSm and a plurality of source line switches SLS1, SLS2, SLS3, . . . , SLSm. The write driver circuit 410 may include a plurality of write drivers WD 420a, 420b, 420c, . . . , 420k. Here, k may be a natural number greater than 3. Each of the plurality of bit-line switches BLS1, BLS2, BLS3, . . . , BLSm may be referred to as a bit-line selection switch and each of the plurality of source line switches SLS1, SLS2, SLS3, . . . , SLSm may be referred to as a source line selection switch.

Each of the plurality of bit-line switches BLS1, BLS2, BLS3, . . . , BLSm may be connected to respective one of the plurality of bit-lines BL1, BL2, BL3, . . . , BLm, and each of the plurality of source line switches SLS1, SLS2, SLS3, . . . , SLSm may be connected to respective one of the plurality of source lines SL1, SL2, SL3, . . . , SLm. The plurality of bit-line switches BLS1, BLS2, BLS3, . . . , BLSm and the plurality of source line switches SLS1, SLS2, SLS3, . . . , SLSm may connect a target write driver among the plurality of write drivers 420a, 420b, 420c, . . . , 420k to a target memory cell, based on the column address C_ADDR. In a write operation, each of the plurality of write drivers 420a, 420b, 420c, . . . , 420k may drive a bit-line of the target memory cell with one of the power supply voltage VDD and the ground voltage VSS and may drive a source-line of the target memory cell with the ground voltage VSS, based on the data DTA, the power supply voltage VDD and the ground voltage VSS.

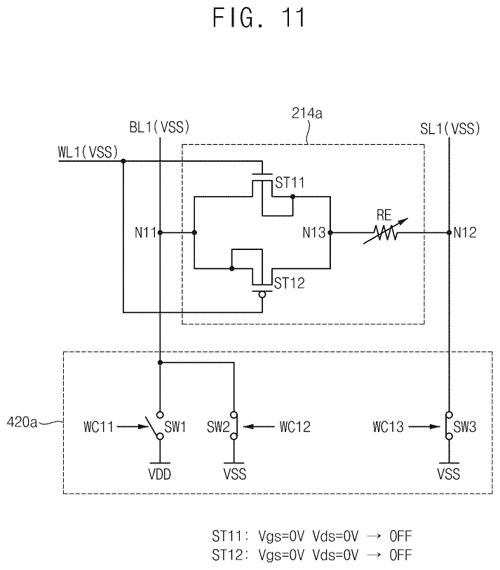

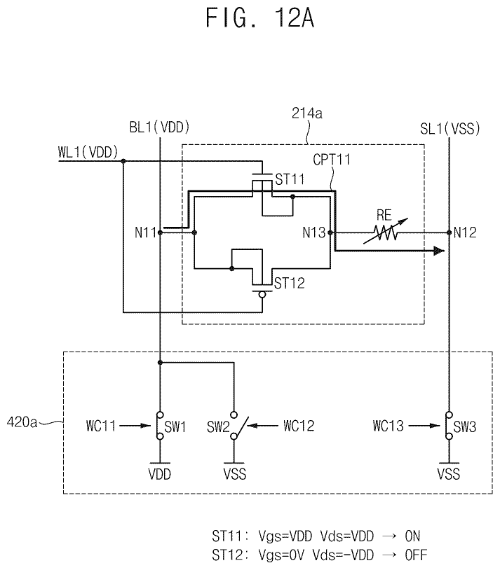

FIG. 11 illustrates an example of a first resistive memory cell and a first write driver in the resistive memory device of FIG. 10 according to example embodiments. In FIG. 11, assuming that the bit-line switch BLS1 and the source line switch SLS1 are turned-on, the bit-line BL1 and the source line SL1 are connected to the first write driver 420a and the first word-line WL1 is selected as a target word-line (e.g., a target page).

As described with reference to FIG. 5A, the first resistive memory cell 241a may include the variable resistor element RE and two selection transistors ST11 and ST12, the variable resistor element RE may be coupled to the first source line SL1, and the two selection transistors ST11 and ST12 having different conductivity type may be coupled to the variable resistor element RE, the first word-line WL1 and the first bit-line BL1 in parallel with respect to each other.

The first write driver 420a may include a first switch SW1, a second switch SW2 and a third switch SW3. The first switch SW1 may selectively provide the power supply voltage VDD to the first bit-line BL1 based on a first write control signal WC11, the second switch SW2 may selectively provide the ground voltage VSS to the first bit-line BL1 based on a second write control signal WC12 and the third switch SW3 may provide the ground voltage VSS to the first source line SL1 based on a third write control signal WC13.

During a stand-by state, the control circuit 300 in FIG. 3 may provide the ground voltage VSS to the first bit-line BL1 by turning-off the first switch SW1 using the first write control WC1 and by turning-on the second switch SW2 using the second write control WC2 and may provide the ground voltage VSS to the first source line SL1 by turning-on the third switch SW3 using the third write control WC3. In addition, the row decoder 220 in FIG. 3 may drive the first word-line WL1 with the ground voltage VSS. The stand-by state may be referred to as a stand-by mode. Therefore, because a gate-source voltage of the first selection transistor ST11 is 0[V] and a drain-source voltage of the first selection transistor ST11 is 0[V], the first selection transistor ST11 is turned-off. In addition, because a gate-source voltage of the second selection transistor ST12 is 0[V] and a drain-source voltage of the second selection transistor ST12 is 0[V], the second selection transistor ST12 is turned-off.

A voltage applied to the first word-line WL1, a voltage applied to the first bit-line BL1 and a voltage applied to the first source line SL1 in FIG. 11 may be referred to as a bias voltage in the stand-by state. Although a configuration of the first write driver 420a is illustrated in FIG. 11, each of the 420b, 420c, . . . , 420k may have a substantially same configuration of the configuration of the first write driver 420a.

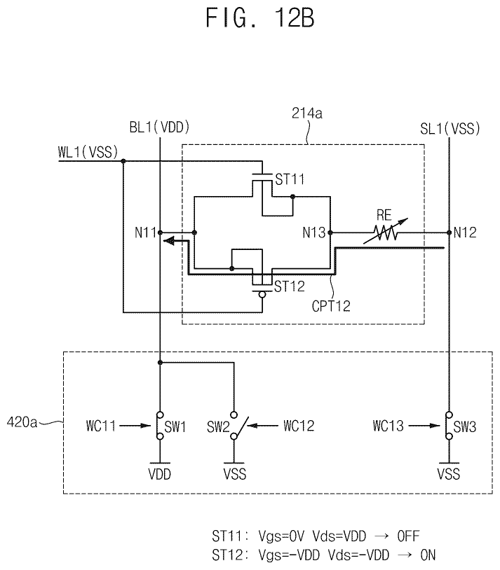

FIG. 12A illustrates an example of a first resistive memory cell and a first write driver in the resistive memory device of FIG. 10 during a set write operation according to example embodiments. In FIG. 12A, descriptions repeated with FIG. 11 will be omitted. During the set write operation, the control circuit 300 in FIG. 3 may provide the power supply voltage VDD to the first bit-line BL1 by turning-on the first switch SW1 using the first write control WC1 and by turning-off the second switch SW2 using the second write control WC2 and may provide the ground voltage VSS to the first source line SL1 by turning-on the third switch SW3 using the third write control WC3. In addition, the row decoder 220 in FIG. 3 may drive the first word-line WL1 with the power supply voltage VDD.

Therefore, because a gate-source voltage of the first selection transistor ST11 is the power supply voltage VDD and a drain-source voltage of the first selection transistor ST11 is the power supply voltage VDD, the first selection transistor ST11 is turned-on and operates in a saturation region. In addition, because a gate-source voltage of the second selection transistor ST12 is 0[V] and a drain-source voltage of the second selection transistor ST12 is negative power supply voltage −VDD, the second selection transistor ST12 is turned-off. Accordingly, because a current path CPT11 passing through the first selection transistor ST11 and the variable resistor element RE is formed (e.g., provided) between the first node N11 and the second node N12, a set current flows through the first selection transistor ST11 and the variable resistor element RE and a reset write operation is performed on the first resistive memory cell 214a such that the variable resistor element RE has a relatively high resistance. Therefore, the first resistive memory cell 214a may store a bit corresponding to a logic low level.

A voltage applied to the first word-line WL1, a voltage applied to the first bit-line BL1 and a voltage applied to the first source line SL1 in FIG. 12A may be referred to as a set write bias voltage. In the conventional resistive memory device, a voltage having a voltage level greater than the power supply voltage is applied to the bit-line for performing a set write operation using a transistor that is operating in a linear region. However, according to example embodiments, because the first selection transistor ST11 operates in the saturation region instead of the linear region, a set current having enough magnitude flows through the first selection transistor ST11 and the variable resistor element RE when the power supply voltage VDD is applied to the first bit-line BL1.

FIG. 12B illustrates an example of a first resistive memory cell and a first write driver in the resistive memory device of FIG. 10 during a reset write operation according to example embodiments. In FIG. 12B, descriptions repeated with FIG. 11 will be omitted.

During the reset write operation, the control circuit 300 in FIG. 3 may provide the power supply voltage VDD to the first bit-line BL1 by turning-on the first switch SW1 using the first write control WC1 and by turning-off the second switch SW2 using the second write control WC2 and may provide the ground voltage VSS to the first source line SL1 by turning-on the third switch SW3 using the third write control WC3. In addition, the row decoder 220 in FIG. 3 may drive the first word-line WL1 with the ground voltage VSS.

Therefore, because a gate-source voltage of the first selection transistor ST11 is 0[V] and a drain-source voltage of the first selection transistor ST11 is the power supply voltage VDD, the first selection transistor ST11 is turned-off. In addition, because a gate-source voltage of the second selection transistor ST12 is negative power supply voltage −VDD and a drain-source voltage of the second selection transistor ST12 is negative power supply voltage −VDD, the second selection transistor ST12 is turned-on and operates in the saturation region. Accordingly, because a current path CPT12 passing through the variable resistor element RE and the first selection transistor ST11 is formed (e.g., provided) between the second node N12 and the first node N11, a set current flows through the first selection transistor ST11 and the variable resistor element RE and a set write operation is performed on the first resistive memory cell 214a such that the variable resistor element RE has a relatively high resistance. Therefore, the first resistive memory cell 214a may store a bit corresponding to a logic high level.

A voltage applied to the first word-line WL1, a voltage applied to the first bit-line BL1 and a voltage applied to the first source line SL1 in FIG. 12B may be referred to as a reset write bias voltage.

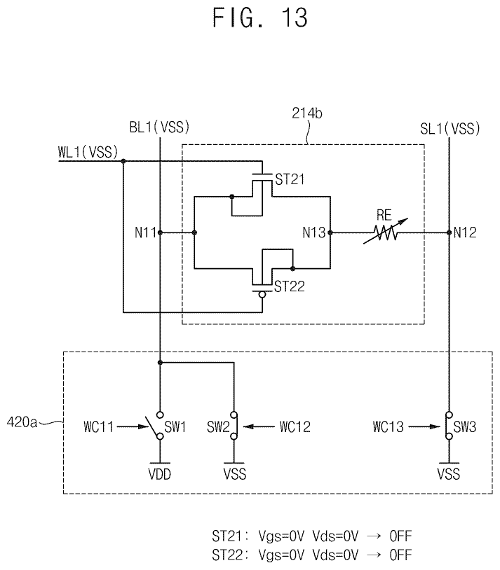

FIG. 13 illustrates an example of a first resistive memory cell and a first write driver in the resistive memory device of FIG. 10 according to example embodiments. In FIG. 13, assuming that the bit-line switch BLS1 and the source line switch SLS1 are turned-on, the bit-line BL1 and the source line SL1 are connected to the first write driver 420a and the first word-line WL1 is selected as a target word-line.

As described with reference to FIG. 5B, the first resistive memory cell 241b may include the variable resistor element RE and two selection transistors ST21 and ST22, the variable resistor element RE may be coupled to the first source line SL1, and the two selection transistors ST21 and ST22 having different conductivity type may be coupled to the variable resistor element RE, the first word-line WL1 and the first bit-line BL1 in parallel with respect to each other.

The first write driver 420a may include a first switch SW1, a second switch SW2 and a third switch SW3. The first switch SW1 may selectively provide the power supply voltage VDD to the first bit-line BL1 based on a first write control signal WC11, the second switch SW2 may selectively provide the ground voltage VSS to the first bit-line BL1 based on a second write control signal WC12 and the third switch SW3 may provide the ground voltage VSS to the first source line SL1 based on a third write control signal WC13.

During a stand-by state, the control circuit 300 in FIG. 3 may provide the ground voltage VSS to the first bit-line BL1 by turning-off the first switch SW1 using the first write control WC1 and by turning-on the second switch SW2 using the second write control WC2 and may provide the ground voltage VSS to the first source line SL1 by turning-on the third switch SW3 using the third write control WC3. In addition, the row decoder 220 in FIG. 3 may drive the first word-line WL1 with the ground voltage VSS.

Therefore, because a gate-source voltage of the first selection transistor ST21 is 0[V] and a drain-source voltage of the first selection transistor ST21 is 0[V], the first selection transistor ST21 is turned-off. In addition, because a gate-source voltage of the second selection transistor ST22 is 0[V] and a drain-source voltage of the second selection transistor ST22 is 0[V], the second selection transistor ST22 is turned-off.

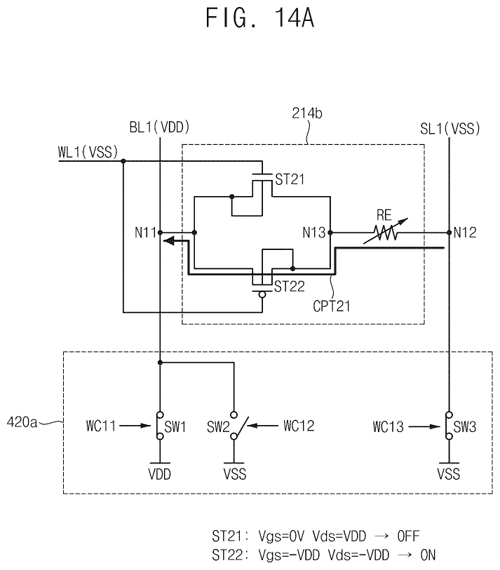

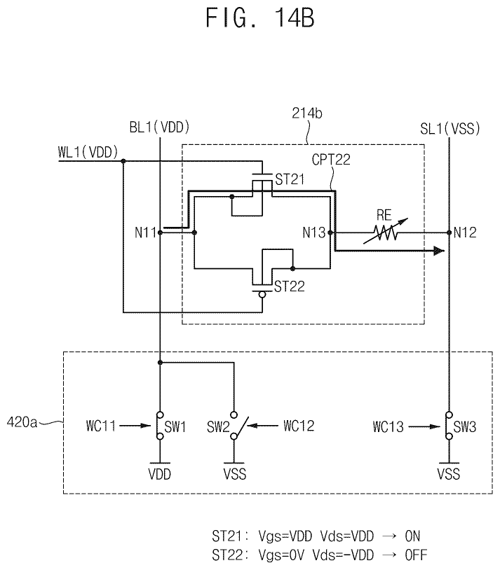

FIG. 14A illustrates an example of a first resistive memory cell and a first write driver in the resistive memory device of FIG. 10 during a set write operation according to example embodiments. In FIG. 14A, descriptions repeated with respect to prior figures will be omitted. During the set write operation, the control circuit 300 in FIG. 3 may provide the power supply voltage VDD to the first bit-line BL1 by turning-on the first switch SW1 using the first write control WC1 and by turning-off the second switch SW2 using the second write control WC2 and may provide the ground voltage VSS to the first source line SL1 by turning-on the third switch SW3 using the third write control WC3. In addition, the row decoder 220 in FIG. 3 may drive the first word-line WL1 with the ground voltage VSS.

Therefore, because a gate-source voltage of the first selection transistor ST21 is 0[V] and a drain-source voltage of the first selection transistor ST21 is the power supply voltage VDD, the first selection transistor ST21 is turned-off. In addition, because a gate-source voltage of the second selection transistor ST22 is negative power supply voltage −VDD and a drain-source voltage of the second selection transistor ST22 is negative power supply voltage −VDD, the second selection transistor ST22 is turned-on and operates in the saturation region. Accordingly, because a current path CPT21 passing through the variable resistor element RE and the first selection transistor ST11 is formed (e.g., provided) between the second node N12 and the first node N11, a set current flows through the first selection transistor ST21 and the variable resistor element RE and a set write operation is performed on the first resistive memory cell 214a such that the variable resistor element RE has a relatively high resistance. Therefore, the first resistive memory cell 214a may store a bit corresponding to a logic low level. A voltage applied to the first word-line WL1, a voltage applied to the first bit-line BL1 and a voltage applied to the first source line SL1 in FIG. 14A may be referred to as a set write bias voltage.

FIG. 14B illustrates an example of a first resistive memory cell and a first write driver in the resistive memory device of FIG. 10 during a reset write operation according to example embodiments. In FIG. 14B, descriptions repeated with prior figures will be omitted. During the reset write operation, the control circuit 300 in FIG. 3 may provide the power supply voltage VDD to the first bit-line BL1 by turning-on the first switch SW1 using the first write control WC1 and by turning-off the second switch SW2 using the second write control WC2 and may provide the ground voltage VSS to the first source line SL1 by turning-on the third switch SW3 using the third write control WC3. In addition, the row decoder 220 in FIG. 3 may drive the first word-line WL1 with the power supply voltage VDD.

Therefore, because a gate-source voltage of the first selection transistor ST21 is the power supply voltage VDD and a drain-source voltage of the first selection transistor ST21 is the power supply voltage VDD, the first selection transistor ST21 is turned-on and operates in a saturation region. In addition, because a gate-source voltage of the second selection transistor ST22 is 0[V] and a drain-source voltage of the second selection transistor ST22 is negative power supply voltage −VDD, the second selection transistor ST22 is turned-off. Accordingly, because a current path CPT22 passing through the first selection transistor ST21 and the variable resistor element RE is formed (e.g., provided) between the first node N11 and the second node N12, a set current flows through the first selection transistor ST21 and the variable resistor element RE and a reset write operation is performed on the first resistive memory cell 214a such that the variable resistor element RE has a relatively high resistance. Therefore, the first resistive memory cell 214a may store a bit corresponding to a logic low level.

A voltage applied to the first word-line WL1, a voltage applied to the first bit-line BL1 and a voltage applied to the first source line SL1 in FIG. 12A may be referred to as a set write bias voltage. In the conventional resistive memory device, a voltage having a voltage level greater than the power supply voltage is applied to the bit-line for performing a set write operation using a transistor that is operating in a linear region. However, according to example embodiments, because the first selection transistor ST21 operates in the saturation region instead of the linear region, a set current having enough magnitude flows through the first selection transistor ST21 and the variable resistor element RE when the power supply voltage VDD is applied to the first bit-line BL1.

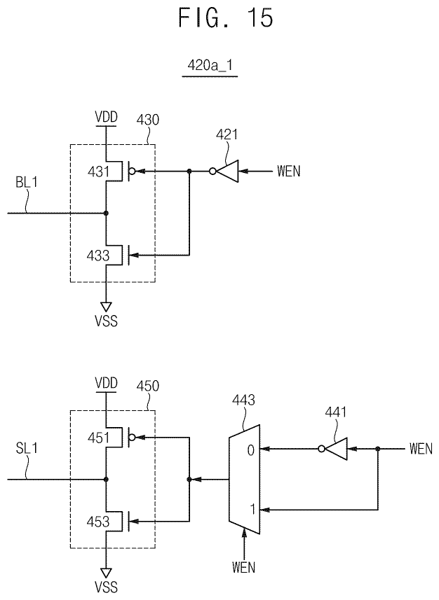

FIG. 15 is a circuit diagram illustrating an example of a first write driver in the resistive memory device of FIG. 10 according to example embodiments. Referring to FIG. 15, a first write driver 420a_1 may be connected to the first bit-line BL1 and the first source line SL1 and may include an inverter 421, a bit-line driver 430, an inverter 441, a multiplexer 443 and a source line driver 450. The bit-line driver 430 may include a PMOS transistor 431 and an NMOS transistor 433 that are coupled between the power supply voltage VDD and the ground voltage VSS and drains of the PMOS transistor 431 and the NMOS transistor 433 may be commonly coupled to the first bit-line BL1.

The source line driver 450 may include a PMOS transistor 451 and an NMOS transistor 453 that are coupled between the power supply voltage VDD and the ground voltage VSS and drains of the PMOS transistor 451 and the NMOS transistor 453 may be commonly coupled to the first source line SL1.

The inverter 421 may invert a write enable signal WEN. The write enable signal WEN may have a logic low level in the stand-by state and may have a logic high level in the write operation. An output of the inverter 421 may applied to gates of the PMOS transistor 431 and the NMOS transistor 433.

The inverter 441 may invert a write enable signal WEN. The multiplexer 443 may receive an output of the inverter 441 and the write enable signal WEN and may provide the output of the inverter 441 and the write enable signal WEN to the gates of the PMOS transistor 431 and the NMOS transistor 433.

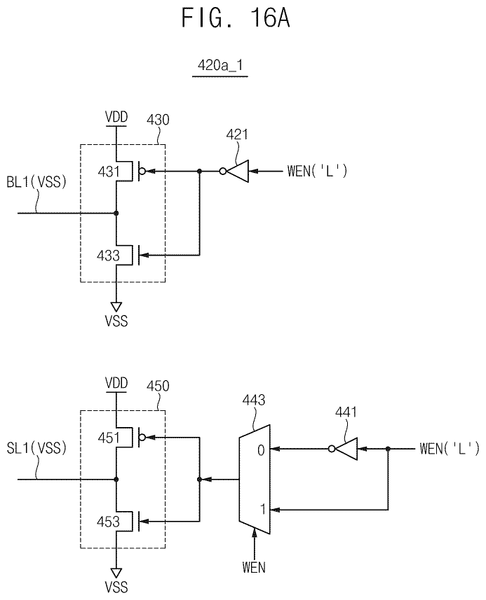

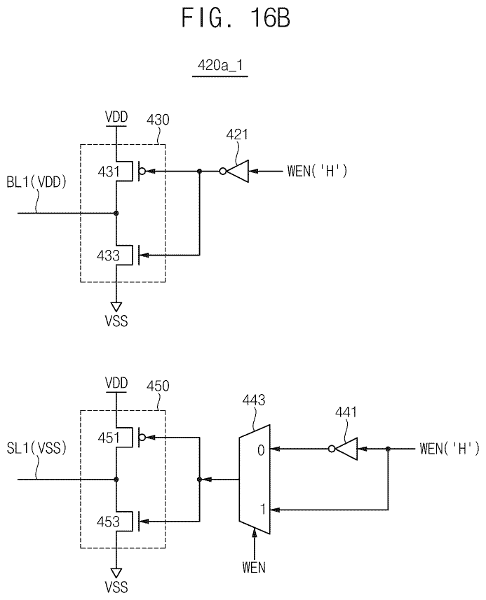

FIG. 16A illustrates an example operation of the first write driver of FIG. 15 in a stand-by state according to example embodiments. Referring to FIG. 16A, because the write enable signal WEN may have a logic low level in the stand-by state, during the stand-by state, the PMOS transistor 431 is turned-off and the NMOS transistor 433 is turned-on in response to the output of the inverter 421, and thus the first bit-line BL1 may be driven with the ground voltage VSS. In addition, because the multiplexer 443 selects the output of the inverter in the stand-by state, during the stand-by state, the PMOS transistor 431 is turned-off and the NMOS transistor 433 is turned-on in response to the output of the multiplexer 443, and thus the first source line SL1 may be driven with the ground voltage VSS.

FIG. 16B illustrates an example operation of the first write driver of FIG. 15 in a write operation according to example embodiments. Referring to FIG. 16B, because the write enable signal WEN may have a logic high level in the set write operation and the reset write operation, during the set write operation and the reset write operation, the PMOS transistor 431 is turned-on and the NMOS transistor 433 is turned-off in response to the output of the inverter 421, and thus the first bit-line BL1 may be driven with the power supply voltage VDD. In addition, because the multiplexer 443 selects the write enable signal WEN, during the set write operation and the reset write operation, the PMOS transistor 431 is turned-off and the NMOS transistor 433 is turned-on in response to the output of the multiplexer 443, and thus the first source line SL1 may be driven with the ground voltage VSS.

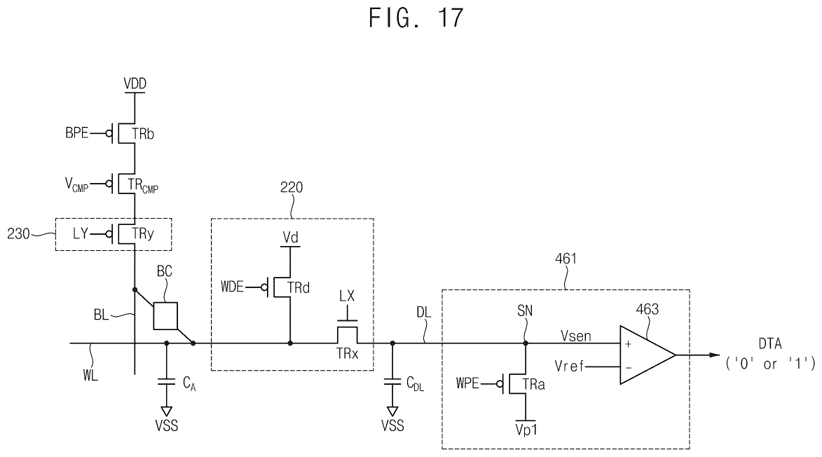

FIG. 17 illustrates a circuit diagram illustrating components associated with performing a read operation of a resistive memory device according to example embodiments. Referring to FIG. 17, a word-line WL may be connected to one end of a resistive memory cell BC, and a bit-line BL may be connected to the other end of the resistive memory cell BC. The row decoder 220 may be connected to the word-line WL. For example, the row decoder 220 may include a word-line selection transistor TRx and a discharge transistor TRd. The word-line selection transistor TRx may be turned on or off in response to a word line selection signal LX. When the word-line selection transistor TRx is turned on, the word-line WL may be connected to a sense amplifier 461 through a data line DL. The discharge transistor TRd may be turned on or off in response to a discharge enable signal WDE. When the discharge transistor TRd is turned on, a discharge voltage Vd may be applied to the word line WL. For example, the discharge voltage Vd may be the ground voltage VSS.

The column decoder 230 may be connected to the bit-line BL and may include a bit-line selection transistor TRy. Also, the column decoder 230 may further include a discharge transistor. The bit-line selection transistor TRy may be connected to control switches, for example, a clamping transistor TR_{CMP} and a bit-line precharge transistor TRb. The bit-line precharge transistor TRb and the clamping transistor TR_{CMP} may be understood as components of the sense amplifier 461. The bit-line selection transistor TRy is turned on or off in response to a bit-line selection signal LY. The bit-line precharge transistor TRb may be turned on or off in response to a bit-line precharge enable signal BPE. In this case, the clamping transistor TR_{CMP} may be controlled to apply a certain voltage to the bit-line BL based on a clamping voltage V_{CMP}.

The sense amplifier 461 may include a word-line precharge transistor TRa and a comparator 463. The word-line precharge transistor TRa may be turned on or off in response to a word-line precharge enable signal WPE. When the word line selection transistor TRx and the word-line precharge transistor TRa are turned-on, a first precharge voltage Vp1 may be applied to the word-line WL. The word-line WL and the bit-line BL may each include a parasitic capacitor, and the capacitance of the parasitic capacitor of the word-line WL, for example, a word-line capacitor CA, may be less than that of the parasitic capacitor of the bit-line BL. Accordingly, the comparator 463 may be connected to the word-line WL having relatively little influence by the parasitic capacitor and may sense the voltage level of the word-line WL, thereby reading data of a selected resistive memory cell BC. The data line DL may include a parasitic capacitor, and the capacitance of the parasitic capacitor of the data line DL, for example, may be a data line capacitor C_{DL}.

The comparator 463 may compare a sensing voltage Vsen of a sensing node SN, for example a voltage level of the data line DL (in this case, the voltage level of the data line DL is the same as the voltage level of the word-line WL), with a reference voltage Vref, and may output a comparison result as data DTA. For example, when the resistive memory cell BC is in a set state, the sensing voltage Vsen may be higher than the reference voltage Vref, and the comparator 463 may output ‘1’ as the data DTA. When the resistive memory cell BC is in a reset state, the sensing voltage Vsen may be lower than the reference voltage Vref, and the comparator 463 may output ‘0’ as the data DTA. The resistive memory cell BC may employ the resistive memory cell 214a of FIG. 5A or resistive memory cell 214b of FIG. 5B.

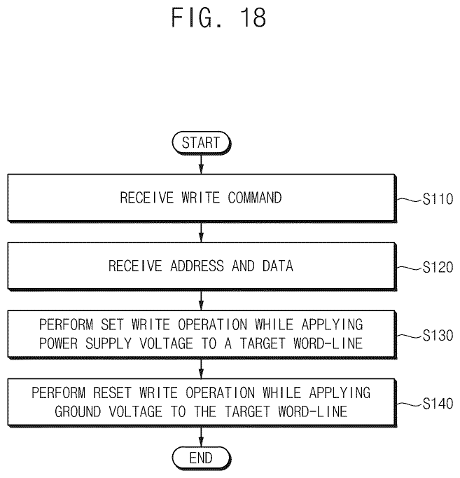

FIG. 18 is a flow chart illustrating a method of operating a resistive memory device according to example embodiments. In FIG. 18, assuming that the resistive memory cell 214 in FIG. 3 includes the resistive memory cell 214a of FIG. 5A.

Referring to FIGS. 1, 3 through 5A, 10 through 12B and 18, the resistive memory device 200 receives a write command from an external memory controller 100 (operation S110). The resistive memory device 200 receives a data DTA and an address ADDR from the external memory controller 100 (operation S120).

The control circuit 300 performs a set write operation on a target page (operation S130) by applying the power supply voltage VDD to the first word-line WL1 of resistive memory cells of a target page. Each of the resistive memory cells of the target page includes a variable resistor element RE coupled to each of source lines SL1, SL2, SL3, . . . , SLm and two selection transistors ST11 and ST12 having different conductivity types, the two selection transistors ST11 and ST12 are coupled in parallel to each of the source lines SL1, SL2, SL3, . . . , SLm, the first word-line WL1 and each of bit-lines BL1, BL2, BL3, . . . , BLm, and the each of the source lines BL1, BL2, BL3, . . . , BLm is coupled to the column decoder 230 and write drivers 420a, 420b, 420c, . . . , 420k.

As described with reference to FIG. 5A, the first selection transistor ST11 may include NMOS transistor having a first conductivity type and a second selection transistor ST12 may include a PMOS transistor having a second conductivity type different from the first conductivity type. The first selection transistor ST11 may be coupled between the first node N11 coupled to the first bit-line BL1 and the third node N13 coupled to the variable resistor element RE, may have a gate coupled to the first word-line WL1 and may have a body coupled to the third node N13. The second selection transistor ST12 may be coupled between the first node N11 and the third node N13, may have a gate coupled to the first word-line WL1 and may have a body coupled to the first node N11.

The control circuit 300 performs a reset write operation on the target page (operation S140) by applying the ground voltage VSS to the first word-line WL1.

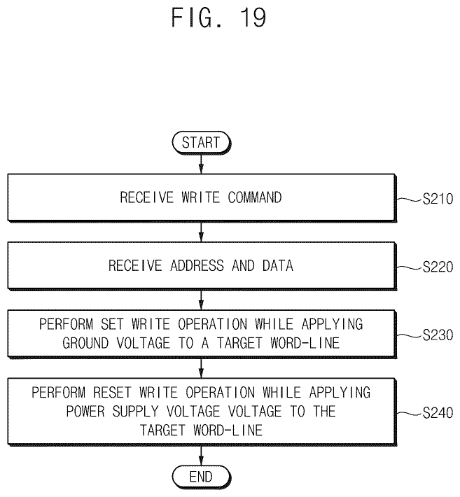

FIG. 19 is a flow chart illustrating a method of operating a resistive memory device according to example embodiments. In FIG. 19, assuming that the resistive memory cell 214 in FIG. 3 includes the resistive memory cell 214b of FIG. 5B.

Referring to FIGS. 1, 3 through 5B, 13 through 14B and 19, the resistive memory device 200 receives a write command from an external memory controller 100 (operation S210). The resistive memory device 200 receives a data DTA and an address ADDR from the external memory controller 100 (operation S220).

The control circuit 300 performs a set write operation on a target page (operation S230) by applying the ground voltage VSS to the first word-line WL1 of resistive memory cells of the target page. Each of the resistive memory cells of the target page includes a variable resistor element RE coupled to each of source lines SL1, SL2, SL3, . . . , SLm and two selection transistors ST21 and ST22 having different conductivity types, the two selection transistors ST21 and ST22 are coupled in parallel to each of the source lines SL1, SL2, SL3, . . . , SLm, the first word-line WL1 and each of bit-lines BL1, BL2, BL3, . . . , BLm, and the each of the source lines BL1, BL2, BL3, . . . , BLm is coupled to the column decoder 230 and write drivers 420a, 420b, 420c, . . . , 420k.

As described with reference to FIG. 5B, the first selection transistor ST21 may include an NMOS transistor having a first conductivity type and a second selection transistor ST22 may include a PMOS transistor having a second conductivity type different from the first conductivity type.

The first selection transistor ST21 may be coupled between the first node N11 coupled to the first bit-line BL1 and the third node N13 coupled to the variable resistor element RE, may have a gate coupled to the first word-line WL1 and may have a body coupled to the first node N11. The second selection transistor ST12 may be coupled between the first node N11 and the third node N13, may have a gate coupled to the first word-line WL1 and may have a body coupled to the third node N13.

The control circuit 300 performs a reset write operation on the target page (operation S240) by applying the power supply voltage VDD to the first word-line WL1.

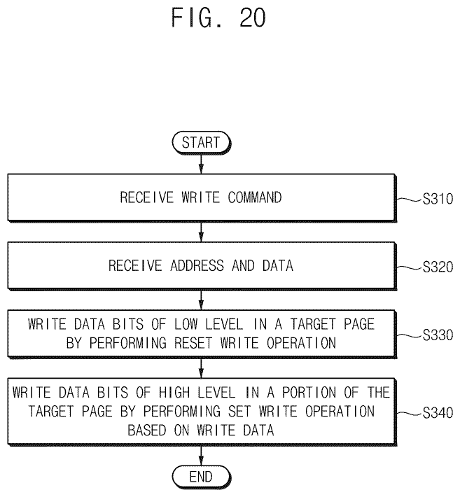

FIG. 20 is a flow chart illustrating a method of operating a resistive memory device according to example embodiments. In FIG. 20, assuming that the resistive memory cell 214 in FIG. 3 includes the resistive memory cell 214a of FIG. 5A or the resistive memory cell 214b of FIG. 5B. Referring to FIGS. 1, 3 through 17 and 20, the resistive memory device 200 receives a write command from an external memory controller 100 (operation S310). The resistive memory device 200 receives a data DTA and an address ADDR from the external memory controller 100 (operation S320).

The write drivers 420a, 420b, 420c, . . . , 420k write data bits having logic low level in a target page by performing a reset write operation on resistive memory cells of the target page (operation S330) Each of the resistive memory cells of the target page includes a variable resistor element RE coupled to each of source lines SL1, SL2, SL3, . . . , SLm and two selection transistors ST21 and ST22 having different conductivity types, the two selection transistors ST21 and ST22 are coupled in parallel to each of the source lines SL1, SL2, SL3, . . . , SLm, the first word-line WL1 and each of bit-lines BL1, BL2, BL3, . . . , BLm, and the each of the source lines BL1, BL2, BL3, . . . , BLm is coupled to the column decoder 230 and write drivers 420a, 420b, 420c, . . . , 420k. That is, the write drivers 420a, 420b, 420c, . . . , 420k perform an erase operation on the resistive memory cells of the target page.

A portion of the write drivers 420a, 420b, 420c, . . . , 420k write data bits having logic high level on a portion of the resistive memory cells of the target page by performing a set write operation on the portion of the resistive memory cells of the target page based on the data DTA (operation S340). The portion of the write drivers 420a, 420b, 420c, . . . , 420k corresponding to the data bits having logic high level perform the set write operation on the portion of the resistive memory cells by applying the power supply voltage of bit-lines of the portion of the resistive memory cells.

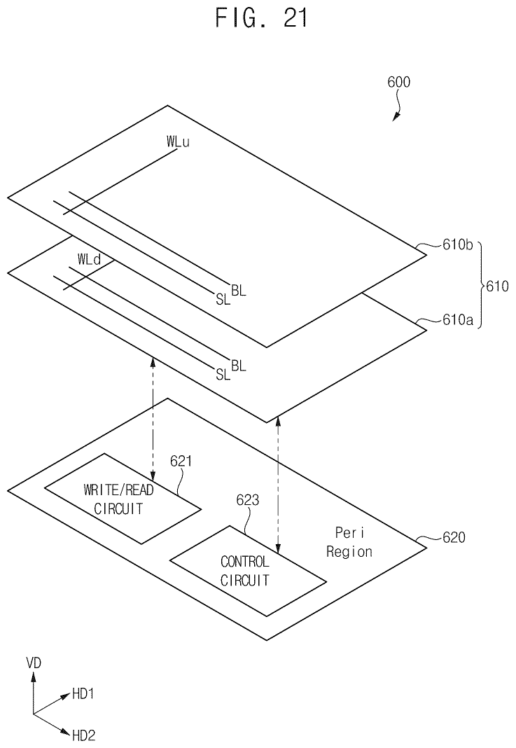

FIG. 21 illustrates a memory device having a cell over peripheral (COP) structure according to example embodiments. Referring to FIG. 21, a memory device 600 may include first and second semiconductor layers 610 and 320 stacked in a vertical direction VD. The first semiconductor layer 610 may include first and second layers 610a and 610b. In some embodiments, the first semiconductor layer 610 may further include at least one layer on the second layer 610b. The first layer 610a may include lower word-lines WLd, the second layer 310b may include upper word-lines WLu, and the first layer 310a and the second layer 310b may share bit-lines BL and source lines SL.

The first layer 610a may further include lower memory cells respectively arranged in regions where the lower word-lines WLd intersect with the bit-lines BL and the source lines SL, and the second layer 610b may further include upper memory cells respectively arranged in regions where the upper word-lines WLu intersect with the bit-lines BL and the source lines SL. The upper word-lines WLu and the lower word-lines WLd may extend in a first horizontal direction HD1 and the bit-lines BL and the source lines SL may extend in a second horizontal direction HD2 crossing the first horizontal direction HD1.

A peripheral circuit region Peri Region including peripheral circuits may be arranged on the second semiconductor layer 620. For example, a write/read circuit 621 and a control circuit 623 may be arranged on the second semiconductor layer 620. However, the present disclosure are not limited thereto, and various types of peripheral circuits related to memory operations may be arranged in the second semiconductor layer 620.

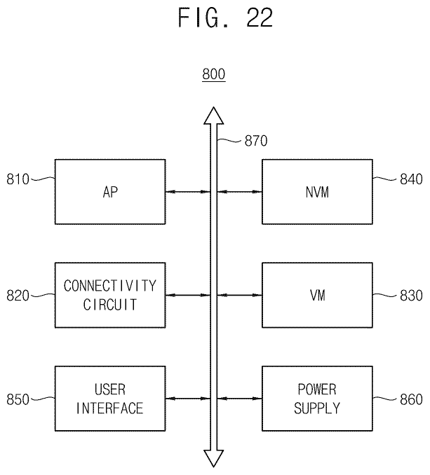

FIG. 22 is a block diagram illustrating a mobile system according to some example embodiments. Referring to FIG. 22, a mobile system 800 includes an application processor (AP) 810, a connectivity circuit 820 a volatile memory device VM 830, a nonvolatile memory device NVM 840, a user interface 850, and a power supply 860 connected through a system bus 870. Any or all of the components of the mobile system 800, such as the AP 810, the connectivity circuit 820, the volatile memory device 830, the nonvolatile memory device 840, the user interface 850, or the power supply 860 may include processing circuitry such as hardware including logic circuits; a hardware/software combination such as a processor executing software; or a combination thereof.

The application processor 810 may execute applications such as at least one of a web browser, a game application, a video player, etc. The connectivity circuit 820 may perform wired and/or wireless communication with an external device. The volatile memory device 830 may store data processed by the application processor 3100, or may operate as a working memory. For example, the volatile memory device 830 may be or include a DRAM, such as at least one of a double data rate synchronous dynamic random access memory (DDR SDRAM), low power DDR (LPDDR) SDRAM, graphics DDR (GDDR) SDRAM, Rambus DRAM (RDRAM), etc.

The nonvolatile memory device 840 may store a boot image for booting the mobile system 800 and other data. The nonvolatile memory device 840 may be or include a phase change random access memory (PRAM) using a phase change materials, a resistance random access memory (RRAM) using a variable resistance material such as complex metal oxide, and/or a magneto-resistive random access memory (MRAM) using a magnetic material. The nonvolatile memory device 840 may employ the resistive memory device 200 of FIG. 3. The user interface 850 may include at least one input device, such as a keypad, a touch screen, etc., and at least one output device, such as a speaker, a display device, etc. The power supply 860 may supply a power supply voltage to the mobile system 800.

As described with reference to FIGS. 1 through 17, the nonvolatile memory device 840 may include a plurality of resistive memory cells, and each of the plurality of resistive memory cells include a variable resistor element coupled to a source line and two selection transistors coupled in parallel to a word-line, a bit-line and the variable resistor element. The nonvolatile memory device 840 may perform a set write operation using one of the two selection transistors, which operates in a saturation region and may perform a reset write operation using the other of the two selection transistors, which operates in a saturation region. Therefore, because the selection transistor operates in the saturation region when the write operation is performed, a write current having enough magnitude is generated when the power supply voltage is applied to the bit-line BL1. Accordingly, the nonvolatile memory device 840 may reduce power consumption and enhance performance by increasing uniformity characteristic of the resistive memory cells.

The example embodiments of present disclosure may be applied to resistive memory devices and systems including the resistive memory devices. The example embodiments of the present disclosure may be applied to various electronic devices and systems that include the self-selecting memories. For example, the inventive concept may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

While the present disclosure has been shown and described with reference to example embodiments thereof, it will be apparent to those of ordinary skill in the art that many modifications in form and details may be made thereto without materially departing from the spirit and scope of the present disclosure as set forth by the following claims.

1. An integrated circuit memory device, comprising:
a memory cell array having a plurality of resistive memory cells therein;
a write/read circuit coupled to the memory cell array through row and column decoders, and configured to perform a write operation that transfers write data into a target page of the memory cell array; and
a control circuit configured to control the row decoder, the column decoder and the write/read circuit in response to a command and an address;
wherein a first resistive memory cell within the memory cell array includes:
a variable resistor element having a first terminal coupled to a first source line; and
two selection transistors of opposite conductivity type coupled in parallel between a first bit line and a second terminal of the variable resistor, and having respective gates connected in common to a first word line, which is coupled to the row decoder;
wherein the first bit line and first source line are coupled to the column decoder; and
wherein a first write driver within the write/read circuit is configured to perform a set write operation on the variable resistor element using one of the two selection transistors and perform a reset write operation on the variable resistor element using the other of the two selection transistors.

2. The device of claim 1, wherein the two selection transistors include:
a first selection transistor of first conductivity type coupled between a first node, which is coupled to the first bit-line, and a third node, which is coupled to the variable resistor element, the first selection transistor including a gate coupled to the first word-line, and a body terminal coupled to the third node; and
a second selection transistor of second conductivity type opposite from the first conductivity type, and coupled in series between the first node and the third node, and in parallel with the first selection transistor, the second selection transistor including a gate coupled to the first word-line, and a body terminal coupled to the first node; and
wherein the variable resistor element is coupled between the third node, and a second node, which is coupled to the first source line.

3. The device of claim 2, wherein, during a stand-by state, the row decoder is configured to turn-off the first selection transistor and the second selection transistor by applying a ground voltage to the first word-line, and the first write driver is configured to apply the ground voltage to the first bit-line and apply the ground voltage to the first source line.

4. The device of claim 2, wherein, during the set write operation, the row decoder is configured to turn-on the first selection transistor and turn-off the second selection transistor by applying a power supply voltage to the first word-line, and the first write driver is configured to provide a current path, which passes through the first selection transistor and the variable resistor element, and between the first node and the second node, by applying the power supply voltage to the first bit-line and by applying a ground voltage to the first source line.

5. The device of claim 4, wherein, during the set write operation, the first selection transistor is configured to operate in a saturation region.

6. The device of claim 2, wherein, during the reset write operation, the row decoder is configured to turn-off the first selection transistor and turn-on the second selection transistor by applying a ground voltage to the first word-line, and the first write driver is configured to provide a current path, which passes through the variable resistor element and the first selection transistor, and between the second node and the first node, by applying the power supply voltage to the first bit-line and by applying a ground voltage to the first source line.

7. The device of claim 6, wherein, during the reset write operation, the second selection transistor is configured to operate in a saturation region.

8. The device of claim 1, wherein the two selection transistors include:
a first selection transistor of first conductivity type coupled between a first node, which is coupled to the first bit-line, and a third node, which is coupled to the variable resistor element, the first selection transistor including a gate electrically coupled to the first word-line, and a body terminal coupled to the first node; and
a second selection transistor of second conductivity type opposite the first conductivity type, and coupled between the first node and the third node, and in parallel with the first selection transistor, the second selection transistor including a gate coupled to the first word-line, and a body terminal coupled to the third node; and
wherein the variable resistor element is coupled between the third node and a second node, which is coupled to the first source line.

9. The device of claim 8, wherein, during a stand-by state, the row decoder is configured to turn-off the first selection transistor and the second selection transistor by applying a ground voltage to the first word-line, and the first write driver is configured to apply the ground voltage to the first bit-line and apply the ground voltage to the first source line.

10. The device of claim 8, wherein, during the set write operation, the row decoder is configured to turn-on the second selection transistor and turn-off the first selection transistor by applying a ground voltage to the first word-line, and the first write driver is configured to provide a current path, which passes through the variable resistor element and the second selection transistor, and between the second node and the first node, by applying a power supply voltage to the first bit-line and by applying a ground voltage to the first source line.

11. The device of claim 10, wherein, during the set write operation, the second selection transistor is configured to operate in a saturation region.

12. The device of claim 2, wherein, during the reset write operation, the row decoder is configured to turn-on the first selection transistor and turn-off the second selection transistor by applying a power supply voltage to the first word-line, and the first write driver is configured to provide a current path, which passes through the first selection transistor and the variable resistor element, and between the first node and the second node, by applying the power supply voltage to the first bit-line and by applying a ground voltage to the first source line.

13. The device of claim 12, wherein, during the reset write operation, the first selection transistor is configured to operate in a saturation region.

14. The device of claim 1, wherein the first write driver includes:
a first switch configured to selectively provide a power supply voltage to the first bit-line based on a first write control signal;
a second switch configured to selectively provide a ground voltage to the first bit-line based on a second write control signal; and
a third switch configured to provide the ground voltage to the first source line based on a third write control signal.

15. The device of claim 1,
wherein a reset write operation is performed on resistive memory cells in the target page by:
applying a ground voltage to the first word-line by the row decoder; and
applying a power supply voltage to bit-lines electrically coupled to the target page and applying the ground voltage to source lines electrically coupled to the target page by a write driver circuit of the write/read circuit; and
wherein a set write operation is performed on resistive memory cells corresponding to bits having a logic high level, among the write data by:
applying the power supply voltage to the first word-line by the row decoder; and
applying the power supply voltage to a portion of the bit-lines electrically coupled to the target page and applying the ground voltage to the source lines electrically coupled to the target page by the write driver circuit.

16. The device of claim 1, wherein the control circuit includes:
a command decoder configured to generate a decoded command by decoding the command received from an external memory controller;
an address buffer configured to generate a row address and a column address based on the address received from the external memory controller, provide the row address to the row decoder and provide the column address to the column decoder; and
a control signal generator configured to generate control signals for controlling the row decoder, the column decoder and the write/read circuit based on the decoded command.

17. The device of claim 1, further comprising:
a first layer and a second layer sharing a plurality of bit-lines and a plurality of source lines, the first layer and the second layer being stacked; and
a peripheral circuit region disposed under the first layer;
wherein each of the first layer and the second layer includes the plurality of resistive memory cells disposed at intersections of a plurality of word-lines, the plurality of bit-lines and the plurality of source lines; and
wherein the control circuit and the write/read circuit are disposed in the peripheral circuit region.

18. A method of operating a resistive memory device including a memory cell array having a plurality of resistive memory cells therein, comprising:
receiving a write command from an external memory controller;
receiving an address and a data from the external memory controller;
performing a reset write operation on a target page by applying a ground voltage to a first word-line, wherein each of the resistive memory cells in the target page includes a variable resistor element coupled to each of source lines and two selection transistors having different conductivity types, the two selection transistors being coupled in parallel to each of the source lines, a first word-line and each of bit-lines, each of the source lines being coupled to the column decoder and write drivers; and
performing a set write operation on a portion of the target page by applying a power supply voltage to the first word-line based on the data.

19. The method of claim 18, wherein the two selection transistors include:
a first selection transistor having a first conductivity type, wherein the first selection transistor is coupled between a first node coupled to each of the bit-lines and a third node coupled to the variable resistor element, includes a gate coupled to the first word-line and includes a body coupled to the first node; and
a second selection transistor having a second conductivity type different from the first conductivity type, wherein the second selection transistor is coupled between the first node and the third node in parallel with the first selection transistor, includes a gate coupled to the first word-line, and a body terminal coupled to the third node; and
wherein the variable resistor element is coupled between the third node and a second node, which is coupled to each of the source lines.

20. A nonvolatile resistive memory device, comprising:
an array of resistive memory cells having respectively pluralities of word, bit and source lines connected thereto;
row and column decoders, and a control circuit coupled to the row and column decoders; and
a write/read circuit coupled to the column decoder and the control circuit, the write/read circuit configured to perform a write operation that transfers write data into a target page of resistive memory cells within the array;
wherein a first resistive memory cell within the array includes:
a variable resistor element having a first terminal coupled to a first source line within the plurality thereof; and
first and second selection transistors configured in combination as a CMOS transmission gate having a first current carrying terminal coupled to a first bit line within the plurality thereof, a second current carrying terminal coupled to a second terminal of the variable resistor element, and a gate control terminal coupled to a first word line within the plurality thereof; and
wherein a first write driver within the write/read circuit is configured to perform a set write operation on the variable resistor element using the first selection transistor within the CMOS transmission gate to establish a first current path in a first direction through the variable resistor element, and perform a reset write operation on the variable resistor element using the second selection transistor within the CMOS transmission gate to establish a second current path in a second direction through the variable resistor element, which is opposite the first direction.

21.-22. (canceled)
